(19) United States
(12) Patent Application Publication
(10) Pub. No.: US 2026/0006719 A1
(43) Pub. Date: Jan. 1, 2026

(54) FABRIC-BASED ANTENNAS FOR WIRELESS POWER APPLICATIONS

(71) Applicant: Yank Technologies, Inc., Brooklyn, NY (US)

(72) Inventors: Milad MIRZAEE, Brooklyn, NY (US); Benjamin TEREBELO, Brooklyn, NY (US); Joshua Aaron YANKOWITZ, Brooklyn, NY (US)

(21) Appl. No.: 19/321,020

(22) Filed: Sep. 5, 2025

Related U.S. Application Data
(63) Continuation of application No. PCT/US2024/018936, filed on Mar. 7, 2024.
(60) Provisional application No. 63/488,817, filed on Mar. 7, 2023.

(51) Int. Cl. H05K 1/03; B32B 5/26; B32B 27/12; H01Q 1/22; H02J 50/10; H05K 1/18

(52) U.S. Cl. CPC H05K 1/038; B32B 5/26; B32B 27/12; H01Q 1/22; H02J 50/10; H05K 1/18; B32B 2250/05; B32B 2307/202; B32B 2457/00

(57) ABSTRACT

Fabric-based antennas for wireless power applications are described. In some aspects, a fabric-based antenna for wireless power applications includes a first support material layer, a second support material layer, and a base material layer disposed between the first support material layer and the second support material layer. In some embodiments, a first separation material layer is disposed between the first support material layer and the base material layer, and a second separation material layer is disposed between the base material layer and the second support material layer.

### CROSS-REFERENCE TO RELATED APPLICATION

This application is a continuation and claims priority to International Application No. PCT/US2024/018936, filed on Mar. 7, 2024, which claims priority to U.S. Provisional Patent Application No. 63/488,817, filed on Mar. 7, 2023, the disclosure of which are hereby incorporated by reference herein in their entirety.

### TECHNICAL FIELD

The present document relates to wireless power transmission technology.

### BACKGROUND

Wireless power solutions can be a means of enabling new features for next-generation devices. However, traditional wire wound antennas cannot meet packaging and performance requirements of certain applications.

### BRIEF SUMMARY

In view of the foregoing, fabric-based antennas are proposed for wireless power that can meet thinner and greater durability requirements for certain applications. Techniques are disclosed for manufacturing, development, and implementation of fabric-based antennas for wireless power applications. In this disclosure, the terms antennas and coils are used interchangeably.

In one example aspect, a fabric-based antenna for wireless power applications includes a first support material layer, a second support material layer, and a base material layer disposed between the first support material layer and the second support material layer. In some embodiments, a first separation material layer is disposed between the first support material layer and the base material layer, and a second separation material layer is disposed between the base material layer and the second support material layer. The base material layer is a fabric-based conductor or conductive foil and less than several centimeters in thickness. One or more feedline wires are electrically connected to conductive material of the base material layer. The first support material layer and/or the second support material layer comprise a plastic or textile-based material with low dissipation factor and dielectric constant.

In another example aspect, a wireless power transmission system includes a transmitter comprising an amplifier and an antenna comprising a first support material layer, a second support material layer, and a base material layer disposed between the first support material layer and the second support material layer. The base material layer is a fabric-based conductor or conductive foil and less than several centimeters in thickness. One or more feedline wires are electrically connected to conductive material of the base material layer and are electrically connected to the amplifier. The first support material layer and/or the second support material layer comprise a plastic or textile-based material with low dissipation factor and dielectric constant.

In another example aspect, a wireless power transmission system includes a receiver printed circuit board (PCB) and an antenna comprising a first support material layer, a second support material layer, and a base material layer disposed between the first support material layer and the second support material layer. The base material layer is a fabric-based conductor or conductive foil and less than several centimeters in thickness. One or more feedline wires are electrically connected to conductive material of the base material layer and are electrically connected to the receiver PCB. The first support material layer and/or the second support material layer comprise a plastic or textile-based material with low dissipation factor and dielectric constant. The receiver PCB includes an AC-DC converter, DC-DC converter, and/or voltage regulation device.

These, and other, aspects are disclosed throughout the document.

### BRIEF DESCRIPTION OF THE DRAWINGS

FIG. 1A and FIG. 1B depict fabric-based antenna construction stackups for wireless power applications according to some embodiments of the disclosed technology.

FIG. 2 depicts an example base material sown to support material according to some embodiments of the disclosed technology.

FIG. 3 depicts example feedline connection for the antenna according to some embodiments of the disclosed technology.

FIG. 4A and FIG. 4B depict an example antenna with tuning and matching PCB according to some embodiments of the disclosed technology.

FIG. 5 depicts an example antenna with tuning and matching PCB and protection cover side perspective view according to some embodiments of the disclosed technology.

FIG. 6 depicts an example antenna with tuning and matching PCB electrically connected to electronics according to some embodiments of the disclosed technology.

FIG. 7 depicts an example antenna sealed with mounting holes according to some embodiments of the disclosed technology.

### DETAILED DESCRIPTION

Wireless power can be a means of enabling new features for next-generation devices. However, current antennas today can often struggle to meet thin packaging requirements (e.g., less than several centimeters), while meeting performance requirements. The proposed technology is the design, development, and manufacturing for novel antennas for wireless power applications.

For the construction of the antenna, there are several potential implementations. In one embodiment, there is a support material, a base material, and a second support material. In another example embodiment, there is a support material, a separation material, a base material, a second separation material, and a second support material.

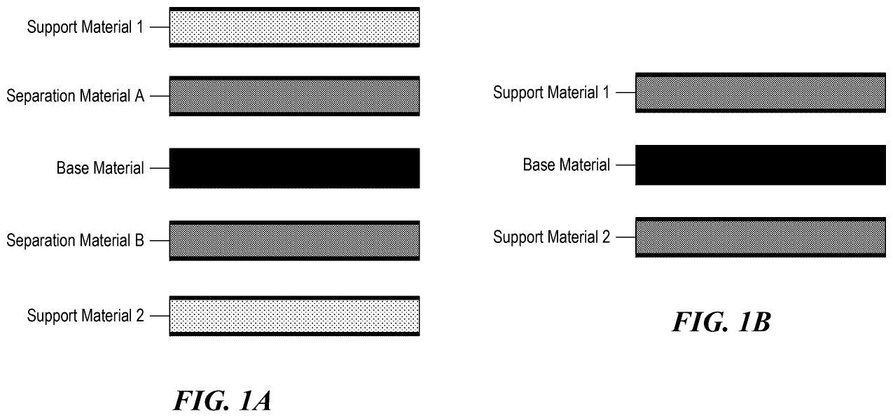

FIG. 1A and FIG. 1B illustrate construction stackups for fabric-based antennas for wireless power applications. In particular, FIG. 1A illustrates a construction stackup with separation materials, while FIG. 1B illustrates a construction stackup with only support materials. The separation materials A & B are selected for a low dielectric constant and dissipation factor for optimal performance. Some example support materials are felt, denim, pellon, and polyester. In some embodiments, the low dissipation factor may include values less than 0.02 or another suitable value. In some embodiments, the low dielectric constant may include values less than 4 or another suitable value. The dissipation factor and/or the dielectric constant may vary based on test frequency and material type. In some embodiments, the support material can be the separation material if the materials meet the durability, environmental, mechanical, and/or other system requirements of the application, which is illustrated in the stackup in FIG. 1B. In the event that the separation materials cannot meet these requirements, support materials can be selected, such as plastics. The separation materials A & B can be the same or distinct. Similarly, the support materials 1 & 2 can be the same or distinct.

The base material is often a fabric-based conductor or conductive foil with low resistance. For wireless power transfer, developing high intrinsic quality (‘Q’) antennas is an important design criteria to improve system efficiency, charging distance, and power delivered to the load. Intrinsic quality is the measure of inductive reactance over resistance. In other words, it is a measure of the energy stored over the energy dissipated for the antenna. It is a dimensionless parameter that is typically used as a barometer for antenna efficiency. The higher the ‘Q’ of the transmitter and receiver antennas, the better they will couple with one another. Therefore, the higher conductivity, the better the base solution for wireless power transfer applications. Some example materials are copper foil, tin-plated copper foil, aluminum foil, aluminum polyester foil, copper polyester taffeta fabric, ripstop silver fabric, and Ni/Cu/Ag plated polyamide fabric. Furthermore, the base material can be less than several millimeters in thickness.

The base material design can be manufactured by press cutting, automatic blade cutting, laser cutting, and water jet cutting. In order to develop a robust structure, the base material can be sandwiched between two layers of separation material. In this instance, the separation materials are directly touching the base material on both sides. The layers can be bonded to the stabilizer by using one of or a combination of the following methods: sewing, adhesives, and fusing.

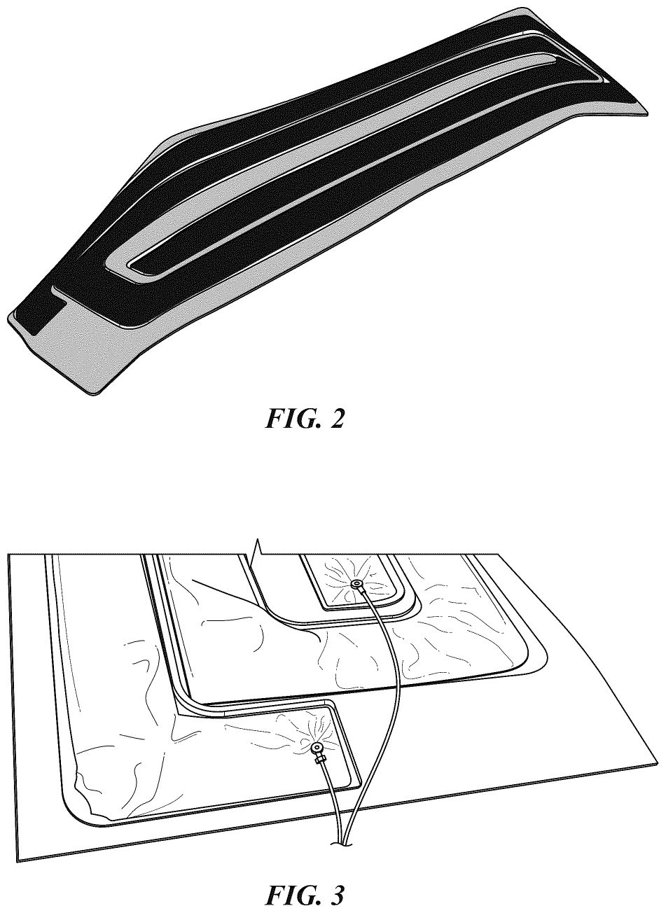

FIG. 2 illustrates an example base material sown to support material. In particular, FIG. 2 shows an example base material design for the conductive traces of the antenna sown onto support material 2 prior the fastening of support material 1. In this instance, the separation material is not needed because it meets the durability, environmental, mechanical, and/or other system requirements of the application. If it does affect the performance of the antenna, the support materials would be directly touching the separation material, not the base material, and can be bonded using similar methods, such as sewing, adhesives, and fusing.

FIG. 3 illustrates an example feedline connection for the antenna. Furthermore, there also must be a method of connecting the feedlines for the antenna in order to be driven by the amplifier in the transmitter or electrically connected to the receiver printed circuit board (PCB) (e.g., tuning capacitors, matching network, AC-DC converter, DC-DC converter, and/or voltage regulation device). These can consist of two wires that are electrically connected to the conductive material of the base layer.

In order to provide a mounting surface for the feedline wires, an eyelet can be crimped to the wires to establish a strong electrical and mechanical connection. A grommet or rivet, such as titanium, steel, and iron, can be used to join the terminal eyelet to the conductor. This provides a robust mechanical connection between the two interfaces. A mechanical substrate can be placed on the opposite side of the base material to allow the grommet or rivet to grip a hard material and not tear through the thin base material. Additional solder can be added to strengthen the electrical connection between the feedlines and the antenna's base layer.

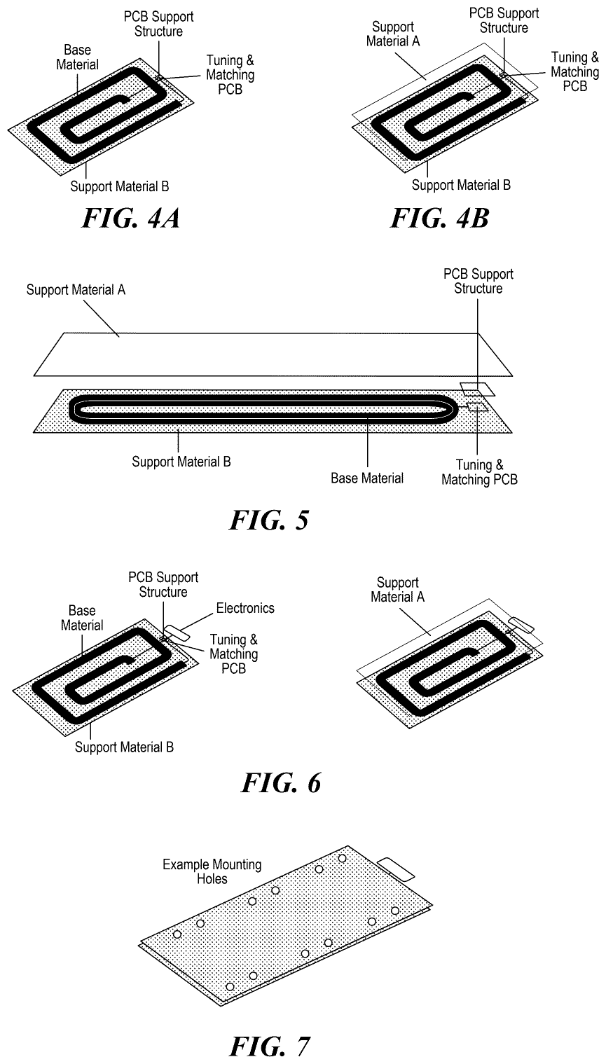

FIGS. 4A and 4B illustrate an example antenna with tuning and matching PCB. In particular, FIG. 4A illustrates an example tuning and matching PCB embedded into the support material B and electrically connected to the feedlines of the antenna, while FIG. 4B illustrates the example antenna with tuning and matching PCB with support material A. These feedlines can be routed from different locations from the base material depending on the particular design for the application. In general, it would be optimal to reduce the length of the feedlines as much as possible to reduce the resistance.

On the Tuning and Matching PCB, capacitors can be placed to substantially excite the antenna at the optimal resonant frequency of the application (e.g., 85 kHz, 100 kHz, 6.78 MHZ, 13.56 MHz, and 27.1 MHz). This can be in series, parallel, series-parallel, and parallel-series configurations. Furthermore, an impedance matching network can be implemented to optimize the impedance match between the antenna and the amplifier that drives it in the transmitter or the converter that is electrically connected in the receiver. The impedance matching network can consist of passive components, such as inductors, capacitors, and resistors. Some example impedance values may be 5, 10, 15, and 50 ohms.

Furthermore, the Tuning and Matching PCB can also have a mechanical clasp or support structure to better guard and preserve the structural integrity of the PCB. This is illustrated by PCB Support Structure in FIG. 4B and FIG. 5, which can be a durable plastic or metal, such as ABS, polycarbonate, PLA, and polypropylene. The purpose of this can be further underscored when it is possible that a person or entity can interact physically with the device. For example, if the antenna is embedded into a car seat or floor of a vehicle, a passenger may be able to physically step on the PCB. Another example can be an automated vehicle, such as an automated guided vehicle, accidentally contacting the antenna on a wall or floor of a factory or fulfillment center.

FIG. 5 illustrates an example antenna with tuning and matching PCB and protection cover side perspective view. In particular, FIG. 5 better illustrates the updated stackup whereby the PCB Support Structure is typically embedded underneath the Support Material A. The PCB Support Structure can be fastened and/or bonded into Support Material B via sewing, adhesives, and fusing. It can also be a flexible printed circuit if thinner PCB substrates are required to meet packaging objectives.

FIG. 6 illustrates an example antenna with tuning and matching PCB electrically connected to electronics. In particular, FIG. 6 illustrates the Electronics module that is electrically coupled to the Tuning & Matching PCB via a differential or single-ended configuration. This can be fastened via crimped wires and connectors, such as friction lock, push-pull, and latch connectors, or soldered directly to the Tuning & Matching PCB and/or PCB in the Electronics. The Tuning & Matching PCB is physically closer to the antenna to optimize the intrinsic quality of the antenna by reducing the length of the feedline wiring and in turn resistance between the conductive base material and the tuning capacitors that substantially excite the antenna at the desired resonant frequency. Meanwhile, the matching components are selected to optimize the impedance match between the amplifier in the Electronics for transmitter embodiments and the converter (e.g., AC-DC and/or DC-DC converters and/or voltage regulation devices) in the Electronics for receiver embodiments. The disclosed antenna system can therefore be used for both transmitter and receiver applications.

FIG. 7 illustrates an example antenna sealed with mounting holes. After the antenna is sealed and bonded with Support Material A, it may be desirable to have mounting holes or cutouts in the Support 1, Support 2, Separation Material A, and Separation Material B layers that do not directly overlap the Base Material. FIG. 7 illustrates example mounting holes. The purpose of these holes is for mounting the antenna to a fixture or mounting products to the antenna. For example, it may be desirable to mount the antenna to the floor of a section of a warehouse to power automated vehicles or mount and bolt a car seat on top of the antenna for wireless power transfer. In these instances, it is important that the mounting holes do not significantly overlap the Base Material because punctures or tears in the conductor may damage the system or reduce its performance.

The following listing of solutions may be preferably implemented by some embodiments.

1. A fabric-based antenna for wireless power applications, comprising: a first support material layer; a second support material layer; and a base material layer disposed between the first support material layer and the second support material layer, wherein: the base material layer is a fabric-based conductor or conductive foil and less than several centimeters in thickness, one or more feedline wires are electrically connected to conductive material of the base material layer, and the first support material layer and/or the second support material layer comprise a plastic or textile-based material with low dissipation factor and dielectric constant.

2. The fabric-based antenna of solution 1, wherein the base material layer comprises a fabric-based conductor or a conductive foil including copper foil, tin-plated copper foil, aluminum foil, aluminum polyester foil, copper polyester taffeta fabric, ripstop silver fabric, and/or Ni/Cu/Ag plated polyamide fabric.

3. The fabric-based antenna of solution 1, wherein the first support material layer and/or the second support material layer comprises a low dissipation factor and dielectric constant plastic including ABS, polycarbonate, PLA, and/or polypropylene, or textile-based material including felt, denim, pellon, and/or polyester.

4. The fabric-based antenna of solutions 1-3, wherein the base material layer is manufactured by press cutting, automatic blade cutting, laser cutting, and/or water jet cutting.

5. The fabric-based antenna of solutions 1-4, wherein the first support material layer and the second support material layer are bonded to the base material layer via sewing, adhesives, and/or fusing.

6. The fabric-based antenna of solutions 1-5, wherein a mounting surface for one or more feedlines is established comprising of one or more eyelets crimped to feedline wires, one or more grommets or rivets such as titanium, steel, or iron, are used to join the one or more eyelets to one or more conductors, and one or more mechanical substrates placed on an opposite side of the base material layer for the one or more grommets or rivets to grip to.

7. The fabric-based antenna of solutions 1-6, wherein a PCB with tuning and matching capacitors are embedded into one of support materials and electrically connected to feedlines of the fabric-based antenna to substantially excite the fabric-based antenna to resonate at an optimal resonant frequency of a target application.

8. The fabric-based antenna of solution 7, wherein the optimal resonant frequency of the target application includes 85 kHz, 100 kHz, 6.78 MHz, 13.56 MHz, and/or 27.1 MHz and capacitors are in series, parallel, series-parallel, or parallel-series configurations.

9. The fabric-based antenna of solutions 7-8, wherein the PCB for tuning and matching has a support structure including a durable plastic or metal to guard and preserve structural integrity of the PCB from environmental and/or mechanical conditions and is fastened or bonded into one or both support materials via sewing, adhesives, and/or fusing.

10. The fabric-based antenna of solutions 1-9, wherein mounting holes or cutouts in one or many support materials that do not significantly overlap with the base material layer are made for mounting the fabric-based antenna to a fixture or product.

11. The fabric-based antenna of solutions 1-10, further comprising:
a first separation material layer disposed between the first support material layer and the base material layer; and
a second separation material layer disposed between the base material layer and the second support material layer.

12. The fabric-based antenna of solution 11, wherein the first separation material layer and/or the second separation material layer comprise a plastic including ABS, polycarbonate, PLA, and/or polypropylene, or textile-based material including felt, denim, pellon, and/or polyester.

13. The fabric-based antenna of solutions 1-12, wherein the first support material layer comprises a first separation material layer, and wherein the second support material layer comprises a second separation material layer.

14. The fabric-based antenna of solutions 1-13, wherein the first support material layer and the second support material layer comprise of same or different materials.

15. The fabric-based antenna of solutions 11-14, wherein the first separation material layer and the second separation material layer comprise of same or different materials.

16. The fabric-based antenna of solutions 11-15, wherein the first separation material layer and the second separation material layer directly touch the base material layer on both sides.

17. The fabric-based antenna of solution 16, wherein the first separation material layer and the second separation material layer are bonded to the base material layer via sewing, adhesives, and/or fusing.

18. The fabric-based antenna of solutions 1-17, wherein the fabric-based antenna is embedded into a floor of a vehicle, a car seat, on a wall, or underneath a warehouse or factory floor.

19. A wireless power transmission system, comprising: a transmitter comprising an amplifier; an antenna comprising: a first support material layer; a second support material layer; and a base material layer disposed between the first support material layer and the second support material layer, wherein: the base material layer is a fabric-based conductor or conductive foil and less than several centimeters in thickness, one or more feedline wires are electrically connected to conductive material of the base material layer and are electrically connected to the amplifier, and the first support material layer and/or the second support material layer comprise a plastic or textile-based material with low dissipation factor and dielectric constant.

20. The wireless power transmission system of solution 19, wherein a PCB with tuning and matching capacitors are embedded into one of support materials and electrically connected to feedlines of the antenna to substantially excite the antenna to resonate at an optimal resonant frequency of a target application and electrically connected to the amplifier.

21. The wireless power transmission system of solutions 19-20, further comprising: a mounting surface for one or more feedlines are established comprising of one or more eyelets crimped to feedline wires, one or more grommets or rivets including titanium, steel, and/or iron, are used to join the one or more eyelets to one or more conductors, and one or more mechanical substrates placed on an opposite side of the base material layer for the one or more grommets or rivets to grip to.

22. A wireless power transmission system, comprising: a receiver printed circuit board (PCB); an antenna comprising: a first support material layer; a second support material layer; and a base material layer disposed between the first support material layer and the second support material layer, wherein: the base material layer is a fabric-based conductor or conductive foil and less than several centimeters in thickness, one or more feedline wires are electrically connected to conductive material of the base material layer and are electrically connected to the receiver PCB, the first support material layer and/or the second support material layer comprise a plastic or textile-based material with low dissipation factor and dielectric constant, and the receiver PCB includes an AC-DC converter, DC-DC converter, and/or voltage regulation device.

23. The wireless power transmission system of solution 22, wherein a PCB with tuning and matching capacitors are embedded into one of support materials and electrically connected to the one or more feedline wires of the antenna to substantially excite the antenna to resonate at an optimal resonant frequency of a target application and electrically connected to the receiver PCB.

24 The wireless power transmission system of solutions 22-23, further comprising: a mounting surface for one or more feedlines are established comprising of one or more eyelets crimped to the one or more feedline wires, one or more grommets or rivets including titanium, steel, and/or iron, are used to join the one or more eyelets to one or more conductors, and one or more mechanical substrates placed on an opposite side of the base material layer for the one or more grommets or rivets to grip to.

The figures and above description provide a brief, general description of a suitable environment in which the invention can be implemented. The above Detailed Description of examples of the invention is not intended to be exhaustive or to limit the invention to the precise form disclosed above. While specific examples for the invention are described above for illustrative purposes, various equivalent modifications are possible within the scope of the invention, as those skilled in the relevant art will recognize. For example, while processes or blocks are presented in a given order, alternative implementations can perform routines having steps/blocks, or employ systems having blocks, in a different order, and some processes or blocks can be deleted, moved, added, subdivided, combined, or modified to provide alternative or sub-combinations. Each of these processes or blocks can be implemented in a variety of different ways. Also, while processes or blocks are at times shown as being performed in series, these processes or blocks can instead be performed or implemented in parallel or can be performed at different times. Further any specific numbers noted herein are only examples: alternative implementations can employ differing values or ranges.

These and other changes can be made to the invention in light of the above Detailed Description. While the above description describes certain examples of the invention, and describes the best mode contemplated, no matter how detailed the above appears in text, the invention can be practiced in many ways. Details of the system can vary considerably in its specific implementation, while still being encompassed by the invention disclosed herein. As noted above, terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed in the specification, unless the above Detailed Description section explicitly defines such terms. Accordingly, the actual scope of the invention encompasses not only the disclosed examples, but also all equivalent ways of practicing or implementing the invention under the claims.

1. A fabric-based antenna for wireless power applications, comprising:
a first support material layer;
a second support material layer; and
a base material layer disposed between the first support material layer and the second support material layer, wherein:
the base material layer is a fabric-based conductor or conductive foil and less than several centimeters in thickness,
one or more feedline wires are electrically connected to conductive material of the base material layer, and
the first support material layer and/or the second support material layer comprise a plastic or textile-based material with low dissipation factor and dielectric constant.

2. The fabric-based antenna of claim 1, wherein the base material layer comprises a fabric-based conductor or a conductive foil including copper foil, tin-plated copper foil, aluminum foil, aluminum polyester foil, copper polyester taffeta fabric, ripstop silver fabric, and/or Ni/Cu/Ag plated polyamide fabric.

3. The fabric-based antenna of claim 1, wherein the first support material layer and/or the second support material layer comprises a low dissipation factor and dielectric constant plastic including ABS, polycarbonate, PLA, and/or polypropylene, or textile-based material including felt, denim, pellon, and/or polyester.

4. The fabric-based antenna of claim 1, wherein the base material layer is manufactured by press cutting, automatic blade cutting, laser cutting, and/or water jet cutting.

5. The fabric-based antenna of claim 1, wherein the first support material layer and the second support material layer are bonded to the base material layer via sewing, adhesives, and/or fusing.

6. The fabric-based antenna of claim 1, wherein a mounting surface for one or more feedlines is established comprising of one or more eyelets crimped to feedline wires, one or more grommets or rivets such as titanium, steel, or iron, are used to join the one or more eyelets to one or more conductors, and one or more mechanical substrates placed on an opposite side of the base material layer for the one or more grommets or rivets to grip to.

7. The fabric-based antenna of claim 1, wherein a PCB with tuning and matching capacitors are embedded into one of support materials and electrically connected to feedlines of the fabric-based antenna to substantially excite the fabric-based antenna to resonate at an optimal resonant frequency of a target application.

8. The fabric-based antenna of claim 7, wherein the optimal resonant frequency of the target application includes 85 kHz, 100 kHz, 6.78 MHz, 13.56 MHz, and/or 27.1 MHz and capacitors are in series, parallel, series-parallel, or parallel-series configurations.

9. The fabric-based antenna of claim 7, wherein the PCB for tuning and matching has a support structure including a durable plastic or metal to guard and preserve structural integrity of the PCB from environmental and/or mechanical conditions and is fastened or bonded into one or both support materials via sewing, adhesives, and/or fusing.

10. The fabric-based antenna of claim 1, wherein mounting holes or cutouts in one or many support materials that do not significantly overlap with the base material layer are made for mounting the fabric-based antenna to a fixture or product.

11. The fabric-based antenna of claim 1, further comprising:
a first separation material layer disposed between the first support material layer and the base material layer; and
a second separation material layer disposed between the base material layer and the second support material layer.

12. The fabric-based antenna of claim 11, wherein the first separation material layer and/or the second separation material layer comprise a plastic including ABS, polycarbonate, PLA, and/or polypropylene, or textile-based material including felt, denim, pellon, and/or polyester.

13. The fabric-based antenna of claim 1, wherein the first support material layer comprises a first separation material layer, and wherein the second support material layer comprises a second separation material layer.

14. The fabric-based antenna of claim 1, wherein the first support material layer and the second support material layer comprise of same or different materials.

15. The fabric-based antenna of claim 11, wherein the first separation material layer and the second separation material layer directly touch the base material layer on both sides.

16. The fabric-based antenna of claim 1, wherein the fabric-based antenna is embedded into a floor of a vehicle, a car seat, on a wall, or underneath a warehouse or factory floor.

17. A wireless power transmission system, comprising:
a transmitter comprising an amplifier; and
an antenna comprising:
a first support material layer;
a second support material layer; and
a base material layer disposed between the first support material layer and the second support material layer, wherein:
the base material layer is a fabric-based conductor or conductive foil and less than several centimeters in thickness,
one or more feedline wires are electrically connected to conductive material of the base material layer and are electrically connected to the amplifier, and
the first support material layer and/or the second support material layer comprise a plastic or textile-based material with low dissipation factor and dielectric constant.

18. The wireless power transmission system of claim 17, wherein a PCB with tuning and matching capacitors are embedded into one of support materials and electrically connected to feedlines of the antenna to substantially excite the antenna to resonate at an optimal resonant frequency of a target application and electrically connected to the amplifier.

19. A wireless power transmission system, comprising:
a receiver printed circuit board (PCB);
an antenna comprising:
a first support material layer;
a second support material layer; and
a base material layer disposed between the first support material layer and the second support material layer, wherein:
the base material layer is a fabric-based conductor or conductive foil and less than several centimeters in thickness,
one or more feedline wires are electrically connected to conductive material of the base material layer and are electrically connected to the receiver PCB,
the first support material layer and/or the second support material layer comprise a plastic or textile-based material with low dissipation factor and dielectric constant, and
the receiver PCB includes an AC-DC converter and/or a DC-DC converter and/or a voltage regulation device.

20. The wireless power transmission system of claim 19, further comprising:
a mounting surface for one or more feedlines are established comprising of one or more eyelets crimped to the one or more feedline wires, one or more grommets or rivets including titanium, steel, and/or iron, are used to join the one or more eyelets to one or more conductors, and one or more mechanical substrates placed on an opposite side of the base material layer for the one or more grommets or rivets to grip to.
